(19) United States
(12) Patent Application Publication
(10) Pub. No.: US 2007/0215949 A1
(43) Pub. Date: Sep. 20, 2007

(54) Semiconductor device including MOS transistor having LOCOS offset structure and manufacturing method thereof

(76) Inventor: Masato Kijima, Hyogo (JP)

Correspondence Address: COOPER & DUNHAM, LLP, 1185 AVENUE OF THE AMERICAS, NEW YORK, NY, 10036, US

(21) Appl. No.: 11/724,428

(22) Filed: Mar. 15, 2007

(30) Foreign Application Priority Data
Mar. 20, 2006 (JP) 2006-076028

(51) Int. Cl. H01L 23/62

(52) U.S. Cl. 257/355

(57) ABSTRACT

A disclosed semiconductor device includes: a semiconductor substrate; at least one normal transistor disposed on the semiconductor substrate; and at least one LOCOS offset transistor disposed on the semiconductor substrate. The normal transistor has an LDD region between a channel and a source and between the channel and a drain. And the LOCOS offset transistor has no LDD region between a channel and a source and between the channel and a drain.

### BACKGROUND OF THE INVENTION

1. Field of the Invention

The present invention generally relates to a technique for manufacturing a high-voltage MOS transistor having a LOCOS (LOCal Oxidation of Silicon) offset structure and a normal low-voltage transistor on the same semiconductor substrate and more particularly to a technique for manufacturing a high-voltage MOS transistor having the LOCOS structure capable of reducing an off-leakage current even when a source and a drain are reversed and a normal low-voltage transistor on the same semiconductor substrate. The present invention is especially effective when applied to a transistor constituting a boost DC/DC converter.

2. Description of the Related Art

In MOS transistor techniques, it is well-known that an off-leakage current in a Pch transistor is reduced when an impurity with low concentration is implanted between a source and a channel or between a drain and the channel and a region (what is called a P−region) in which P− (boron implantation) is formed on a surface thereof and N− (phosphorus implantation) is formed below the surface is disposed. In this Pch transistor structure, an N-portion formed below a P-portion of the P−region is referred to as a punch-through stopper layer (PTS layer).

FIG. 5 is a diagram showing a structure in which the above-mentioned P−region is disposed so as to reduce the off-leakage current in a normal low-voltage Pch transistor (5V transistor, for example) which has been conventionally proposed.

As shown in FIG. 5, a deep N-well (DNW) 101 is formed on a P substrate 100 and P+regions to be used as a source and a drain are disposed in the deep N-well (DNW) 101 at predetermined intervals. The P−regions in which the P-portion is formed on the surface thereof and the N-portion is formed below the surface are disposed on a channel portion between the P+regions, namely, between the source (+P) and the channel and between the drain (+P) and the channel. Further, a gate electrode 102g is disposed on the channel via an insulating film 102ox. By disposing the region (P−region) in which the P-portion is formed on the surface and the N-portion is formed below the surface, it is possible to reduce a distance between the source and the drain while maintaining the characteristics of eliminating the off-leakage current when a predetermined voltage is applied between the source and the drain (semiconductor can be miniaturized).

Moreover, MOS transistors having the LOCOS (LOCal Oxidation of Silicon) offset structure having a thick insulating film so as to increase voltage resistance have been conventionally known.

For example, Japanese Laid-Open Patent Application No. 2003-324159 (Patent Document 1) discloses a semiconductor device with a transistor having the LOCOS offset structure in which N-type source and drain are formed at intervals in a P-well so as to reduce the number of photomechanical steps, at least the drain of the source and the drain has an N-type high concentration diffusion layer and an N-type low concentration diffusion layer surrounding the N-type high concentration diffusion layer, the N-type low concentration diffusion layer having lower concentration in comparison with the N-type high concentration diffusion layer. On the same P-type semiconductor substrate, a gate electrode includes an offset N channel-type transistor in which an end relative to the drain is formed on a thick oxide film and a normal N-well for forming a P channel-type MOS transistor. The N-type low concentration diffusion layer and the normal N-well are formed by the same process at the same time.

In the high-voltage MOS transistor, it is possible to dispose the region (P−region) in which the P-portion is formed on the surface and the N-portion is formed below the surface between the source and the channel as described in the above-mentioned normal low-voltage MOS transistor.

FIG. 6 is a diagram showing an example of a structure where the region (P−region) in which the P-portion is formed on the surface and the N-portion is formed below the surface is disposed between the source and the channel of a high-voltage LOCOS offset Pch transistor.

In FIG. 6, reference numeral 200 designates the P-type substrate, reference numeral 201 the deep N-well, reference numeral 202s the source, reference numeral 202g the gate electrode, reference numeral 202d the drain, reference numeral 203 the P−region (LDD (Lightly Doped Drain) structure: a portion of low dopant concentration is included in an end of the drain on a gate side so as to control a short channel effect) in which the P-portion (boron implantation) is formed on the surface and the N-portion (phosphorus implantation) is formed below the surface, reference numeral 204 a channel region, reference numeral 206 an N-well, and reference numeral 208 a P-well.

In a structure in which the low-voltage transistor and the high-voltage transistor are disposed on the same semiconductor substrate, the P-portion of the p−region and an N-portion of an N−region are configured such that gate length dependence of a threshold Vth of the low-voltage transistor is flat. However, in a high voltage (15V-Pch), a thickness Tox of a gate insulating film is 40 nm (10 nm in a normal low-voltage transistor), so that an N-type PTS layer of phosphorus is formed on the surface and an amount of boron implantation in the substrate is reduced in comparison with a normal case and the P-portion and the N-portion are considered to be out of balance.

In other words, the threshold Vth in the vicinity of the P−region is presumed to be high and the threshold Vth in the channel region is presumed to be low, and the P−region and the channel region are serially connected, so that the threshold is determined from a higher threshold. By contrast, when the drain is not provided with the LOCOS insulating film, the Vth is considered to be low in accordance with an increase of drain voltage because an influence of a p-layer is eliminated when a depletion layer is extended.

In the Pch transistor having the LOCOS offset structure shown in FIG. 6, when a P−region (LDD (Lightly Doped Drain)) 203 in which the P-portion (boron implantation) is formed on the surface and the N-portion (phosphorus implantation) is formed below the surface is not manufactured, the off-leakage current is eliminated.

In this case, it is necessary to adjust and control concentration of impurity in the channel region such that the threshold Vth becomes a desired value. In order to eliminate the P−region 203, boron or phosphorus may be implanted in this portion using a mask for a photomechanical process used during manufacturing steps. The same applies in an Nch transistor having the LOCOS offset structure.

In the case of the low-voltage Pch transistor, as mentioned above, the off-leakage current is eliminated by disposing the P−region in which the P-portion (boron implantation) is formed on the surface and the N-portion (phosphorus implantation) is formed below the surface. By contrast, in the case of the Nch transistor, it is possible to eliminate the off-leakage current by disposing an N−region in which the N-portion (phosphorus implantation) is formed on the surface and the P-portion (boron implantation) is formed below the surface.

The following describes an example of a circuit configuration of the high-voltage transistor when voltage applied to the drain and the source is reversed with reference to the drawings.

FIG. 7 is a diagram showing an example of a circuit of a booster circuit previously proposed by the inventors of the present invention.

In FIG. 7, a booster circuit 300 increases voltage of an input voltage Vin input in an input terminal IN and outputs an output voltage Vout from an output terminal OUT.

The booster circuit 300 includes a switching element M1 made of an NMOS transistor, a rectifying device M2 made of a PMOS transistor, a PMOS transistor M3, a PMOS transistor M4, an inverter INV1, an inductor L1, a capacitor C1, and a control circuit 301 for controlling operations of the switching element M1, the rectifying device M2, and the PMOS transistors M3 and M4.

The PMOS transistor M3 constitutes a first MOS transistor, the PMOS transistor M4 constitutes a second MOS transistor, and the control circuit 301 and the inverter INV1 constitute control circuit units. Further, the switching element M1, the rectifying device M2, the PMOS transistors M3 and M4, the inverter INV1, and the control circuit 301 may be integrated on a single IC.

The inductor L1 and the rectifying device M2 are serially connected between the input terminal IN and the output terminal OUT and the capacitor C1 is connected between the output terminal OUT and an earth voltage. The switching element M1 is connected between a connection portion of the inductor L1 and the rectifying device M2 and an earth voltage. Each gate of the switching element M1 and the rectifying device M2 is connected to the control circuit 301.

A substrate gate of the switching element M1 is connected to the earth voltage. The PMOS transistors M3 and M4 are serially connected and the series circuit is connected in parallel with the rectifying device M2. A sleep signal SLP from the control circuit 301 is input to a gate of the PMOS transistor M3 and an input terminal of the inverter INV1. The sleep signal SLP is input to a gate of the PMOS transistor M4 via the inverter INV1. A connection portion between the PMOS transistors M3 and M4 is connected to a substrate gate of the rectifying device M2. Each substrate gate of the PMOS transistors M3 and M4 is connected to the connection portion. In accordance with this, parasitic diodes D3 and D4 are formed for the PMOS transistors M3 and M4.

In such a configuration, upon boosting operation, the control circuit 301 causes the sleep signal SLP to become a high level and controls the switching element M1 and the rectifying device M2 such that the switching element M1 and the rectifying device M2 are switched on/off in a complementary manner. Further, while the boosting operation is stopped, the control circuit 301 switches off both of the switching element M1 and the rectifying device M2 and causes the sleep signal SLP to become a low level.

FIG. 8 is a diagram showing an equivalent circuit indicating a connection status of the substrate gate of the rectifying device M2 and a connection status of the parasitic diodes of the PMOS transistors M3 and M4 upon operation of the booster circuit 300. FIG. 9 is a diagram showing an equivalent circuit indicating the connection status of the substrate gate of the rectifying device M2 and the connection status of the parasitic diodes of the PMOS transistors M3 and M4 while the operation of the booster circuit 300 is stopped.

In FIG. 8, upon boosting operation, the sleep signal SLP is in a high level, so that the PMOS transistor M3 is switched off and the PMOS transistor M4 is switched on. The substrate gate of the rectifying device M2 is connected to the output terminal OUT. An anode of the parasitic diode D3 is connected to a connection portion between the inductor L1 and the rectifying device M2 and a cathode of the parasitic diode D3 is connected to the substrate gate of the rectifying device M2.

Next, in FIG. 9, while the boosting operation is stopped (upon sleeping), the sleep signal SLP is in the low level, so that the PMOS transistor M3 is switched on and the PMOS transistor M4 is switched off. The substrate gate of the rectifying device M2 is connected to the connection portion between the inductor L1 and the rectifying device M2. An anode of the parasitic diode D4 is connected to the output terminal OUT and a cathode of the parasitic diode D4 is connected to the substrate gate of the rectifying device M2. In accordance with this, even when voltage of the output terminal OUT is reduced, the input voltage Vin is not output to the output terminal OUT.

Patent Document 1: Japanese Laid-Open Patent Application No. 2003-324159

In view of this, when a LOCOS offset transistor is used as the rectifying device M2 for high voltage, it is necessary to dispose the LOCOS insulating film on an input (Vin) side taking into consideration boosting operations. However, when an LED is connected as a load, for example, a reverse voltage may be applied upon sleeping, namely, the drain and the source may be reversed. In such a case, a high-voltage transistor with a small off-leakage current is desired and preferably the P−region (LDD (Lightly Doped Drain)) in which the P-portion (boron implantation) is formed on the surface and the N-portion (phosphorus implantation) is formed below the surface is not disposed between the channel and the source.

However, there has been no disclosed manufacturing method for manufacturing a high-voltage LOCOS offset transistor configured to eliminate the off-leakage current without the P−region (LDD (Lightly Doped Drain)) and a normal low-voltage transistor configured to eliminate the off-leakage current with the P−region on the same semiconductor substrate.

### SUMMARY OF THE INVENTION

It is a general object of the present invention to provide an improved and useful semiconductor device and a method for manufacturing the semiconductor device in which the above-mentioned problems are eliminated.

A more specific object of the present invention is to provide a semiconductor device including a high-voltage LOCOS offset transistor configured to eliminate the off-leakage current without the LDD region and a normal low-voltage transistor configured to eliminate the off-leakage current with the LDD region on the same semiconductor substrate and to provide a method for manufacturing the semiconductor device in an efficient manner.

According to one aspect of the present invention, there is provided a semiconductor device comprising: a semiconductor substrate; at least one normal transistor disposed on the semiconductor substrate; and at least one LOCOS offset transistor disposed on the semiconductor substrate, wherein the normal transistor has an LDD region between a channel and a source and between the channel and a drain, and the LOCOS offset transistor has no LDD region between a channel and a source and between the channel and a drain.

According to another aspect of the present invention, in the semiconductor device, the LDD region includes two low concentration diffusion layer regions of different conductivity types.

According to another aspect of the present invention, there is provided a method for manufacturing a semiconductor device including a semiconductor substrate, at least one LOCOS offset transistor disposed on the semiconductor substrate, and at least one normal transistor disposed on the semiconductor substrate through a photomechanical process and an ion implantation technique, the method comprising the steps of: forming a normal N-well including a region of a normal Pch transistor, an N-well including a region of a LOCOS offset Pch transistor, and an N-type low concentration diffusion layer of a LOCOS offset Nch transistor on the semiconductor substrate; forming a normal P-well including a region of a normal Nch transistor and a P-well including a region of the LOCOS offset Nch transistor; forming a P-type low concentration diffusion layer of the LOCOS offset Pch transistor; forming a LOCOS oxide film on a surface of the substrate using a LOCOS process; forming gate oxide films of the normal Pch transistor, the normal Nch transistor, the LOCOS offset Pch transistor, and the LOCOS offset Nch transistor; forming an N-type LDD region (N−region) by implanting phosphorus or arsenic in a surface of the normal P-well and implanting boron below the surface; forming a P-type LDD region (P−region) by implanting boron or BF2 in a surface of the normal N-well and implanting phosphorus below the surface; forming LDD side walls on both sides of gate electrodes of the normal Pch transistor and the normal Nch transistor; forming a source and a drain of the normal Nch transistor and a source and a drain of the LOCOS offset Nch transistor by implanting phosphorus or arsenic in the normal P-well, the P-well including the region of the LOCOS offset Nch transistor, and the N-type low concentration diffusion layer of the LOCOS offset Nch transistor; and forming a source and a drain of the normal Pch transistor and a source and a drain of the LOCOS offset Pch transistor by implanting boron or BF2 in the normal N-well, the N-well including the region of the LOCOS offset Pch transistor, and the P-type low concentration diffusion layer of the LOCOS offset Pch transistor.

According to another aspect of the present invention, in the method for manufacturing a semiconductor device, one of the normal Pch transistor and the normal Nch transistor is omitted.

According to another aspect of the present invention, in the method for manufacturing a semiconductor device, one of the LOCOS offset Pch transistor and the LOCOS offset Nch transistor is omitted.

According to the present invention, by employing the above-mentioned structure, it is possible to efficiently manufacture a given combination of a high-voltage transistor and a low-voltage transistor without an off-leakage current on the same semiconductor substrate.

Other objects, features and advantage of the present invention will become more apparent from the following detailed description when read in conjunction with the accompanying drawings.

### BRIEF DESCRIPTION OF THE DRAWINGS

FIG. 1 is a cross-sectional view showing an example of a semiconductor device according to an embodiment of the present invention;

FIG. 2 is a first cross-sectional view showing an example of a method for manufacturing a semiconductor device according to an embodiment;

FIG. 3 is a second cross-sectional view showing an example of a method for manufacturing a semiconductor device according to an embodiment;

FIG. 4A is a third cross-sectional view showing an example of a method for manufacturing a semiconductor device according to an embodiment;

FIG. 4B is a cross-sectional view showing details of a method for manufacturing a normal low-voltage Pch transistor.

FIG. 5 is a cross-sectional view showing a structure including a P−region disposed so as to reduce an off-leakage current in a normal low-voltage Pch transistor which has been conventionally proposed;

FIG. 6 is a cross-sectional view showing a structure including a P−region disposed between a source and a channel of a high-voltage LOCOS offset Pch transistor;

FIG. 7 is a diagram showing an example of a configuration of a booster circuit previously proposed;

FIG. 8 is a diagram showing an equivalent circuit indicating a connection status upon operation of the booster circuit shown in FIG. 7; and

FIG. 9 is a diagram showing an equivalent circuit indicating a connection status while operation of the booster circuit shown in FIG. 7 is stopped.

### DETAILED DESCRIPTION OF THE PREFERRED EMBODIMENTS

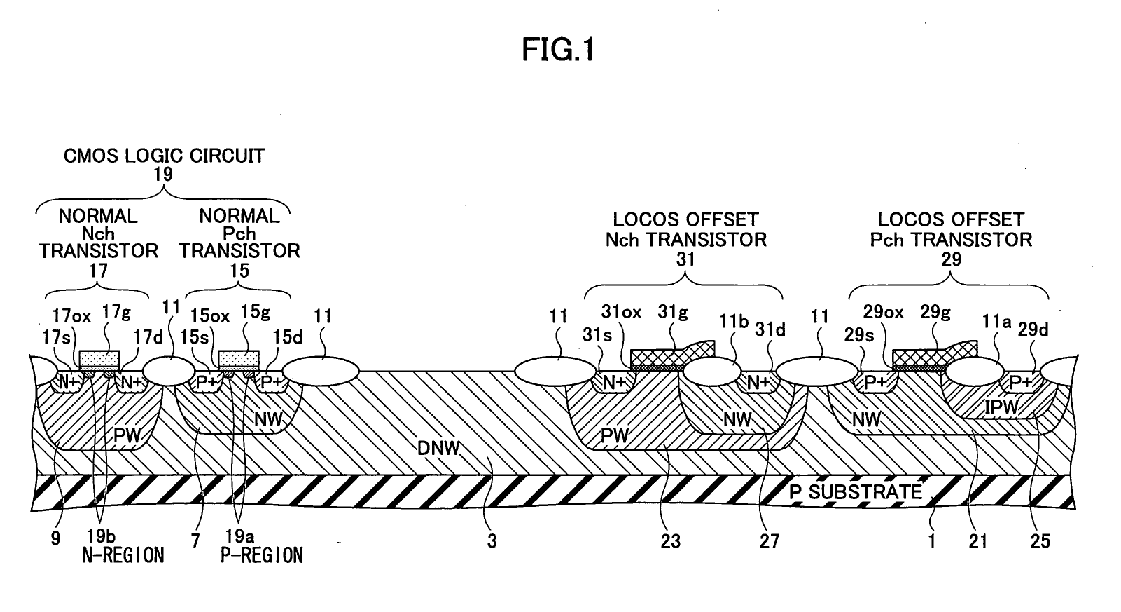

FIG. 1 is a cross-sectional view showing an example of a semiconductor device manufactured in a method for manufacturing a semiconductor device according to the present invention. In the present invention, at least one Nch or Pch LOCOS offset transistor and at least one normal Nch or Pch transistor are manufactured on the same semiconductor substrate. In the present embodiment, four types of transistors, namely, a LOCOS offset Nch transistor, a LOCOS offset Pch transistor, a normal Pch transistor, and a normal Nch transistor are manufactured on the same semiconductor substrate as an example. However, it is possible to apply the present invention to any combination as long as at least one LOCOS offset transistor and at least one normal transistor are used. It is possible to form a CMOS transistor using a normal Nch transistor and a normal Pch transistor.

A deep N-well (DNW) 3 is formed on a P substrate 1. On the P substrate 1, a normal N-well (NW) 7, a normal P-well (PW) 9, an N-well (NW) 21, and a P-well (PW) 23 are formed. On a surface of the P substrate 1, a LOCOS oxide film 11 is formed in a LOCOS method so as to separate the deep N-well 3, the normal N-well 7, the normal P-well 9, the N-well 21, and the P-well 23 from one another.

In the normal N-well 7, a source (P+) 15s and a drain (P+) 15d made of a P-type diffusion layer are formed with a space therebetween. A gate electrode 15g made of a polysilicon film is formed on the normal N-well 7 between the source 15s and the drain 15d via a gate oxide film 15ox. In accordance with this, a normal Pch transistor 15 is formed in a region where the normal N-well 7 is formed.

In the normal P-well 9, a source (N+) 17s and a drain (N+) 17d made of an N-type high concentration diffusion layer are formed with a space therebetween. A gate electrode 17g made of a polysilicon film is formed on the normal P-well 9 between the source 17s and the drain 17d via a gate oxide film 17ox. In accordance with this, a normal Nch transistor 17 is formed in a region where the normal P-well 9 is formed. The normal Pch transistor 15 and the normal Nch transistor 17 constitute a CMOS logic circuit 19.

In the N-well 21, there are formed a source (P+) 29s made of a P-type high concentration diffusion layer and a P-type low concentration diffusion layer (IPW) 25 having a lower concentration of P-type impurity in comparison with the source 29s with a space therebetween. In the P-type low concentration diffusion layer 25, there is formed a drain (p+) 29d made of a P-type high concentration diffusion layer having a higher concentration of P-type impurity in comparison with the P-type low concentration diffusion layer 25 with a space from an end of the source 29s of the N-well 21. The drain of a LOCOS offset Pch transistor 29 is constituted using the P-type low concentration diffusion layer 25 and the drain 29d.

On a surface of the P-type low concentration diffusion layer 25, a LOCOS oxide film 11a is formed while partially overlapping with the drain 29d and having a space from the end of the source 29s of the N-well 21. The LOCOS oxide film 11a and the LOCOS oxide film 11 are formed at the same time.

A gate electrode 29g made of a polysilicon film is formed from a surface of an end of the source 29s relative to the LOCOS oxide film 11a to a surface of the LOCOS oxide film 11a over the N-well 21 between the source 29s and the P-type low concentration diffusion layer 25 and the P-type low concentration diffusion layer 25. The gate electrode 29g is formed on the source 29s, the N-well 21, and the P-type low concentration diffusion layer 25 via a gate oxide film 29 × and an end of the gate electrode 29g relative to the drain 29d is formed on the LOCOS oxide film 11a with a space from the drain 29d.

In the P-well 23, there are formed a source (N+) 31s made of an N-type high concentration diffusion layer and an N-type low concentration diffusion layer (NW) 27 having a lower concentration of N-type impurity in comparison with the source 31s with a space therebetween. In the N-type low concentration diffusion layer 27, there is formed a drain (N+) 31d made of an N-type high concentration diffusion layer having a higher concentration of N-type impurity in comparison with the N-type low concentration diffusion layer 27 with a space from an end of the source 31s of the P-well 23. The drain of a LOCOS offset Nch transistor 31 is constituted using the N-type low concentration diffusion layer 27 and the drain 31d.

On a surface of the N-type low concentration diffusion layer 27, a LOCOS oxide film 11b is formed while partially overlapping with the drain 31d and having a space from the end of the source 31s of the P-well 23. The LOCOS oxide film 11b, the LOCOS oxide film 11, and the LOCOS oxide film 11a are formed at the same time.

A gate electrode 31g made of a polysilicon film is formed from a surface of an end of the source 31s relative to the LOCOS oxide film 11b to a surface of the LOCOS oxide film 11b over the P-well 23 between the source 31s and the N-type low concentration diffusion layer 27 and the N-type low concentration diffusion layer 27. The gate electrode 31g is formed on the source 31s, the P-well 23, and the N-type low concentration diffusion layer 27 via a gate oxide film 31 × and an end of the gate electrode 31g relative to the drain 31d is formed on the LOCOS oxide film 11b with a space from the drain 31d.

In the present embodiment, the normal N-well 7, the N-well 21, and the N-type low concentration diffusion layer 27 are formed at the same time in the same photomechanical process and impurity introduction process. Further, the normal P-well 9 and the P-well 23 are formed at the same time in the same photomechanical process and impurity introduction process. Moreover, an IP well 5 and the P-type low concentration diffusion layer 25 are formed at the same time in the same photomechanical process and impurity introduction process. A method for manufacturing this embodiment is described with reference to FIGS. 1 to 3.

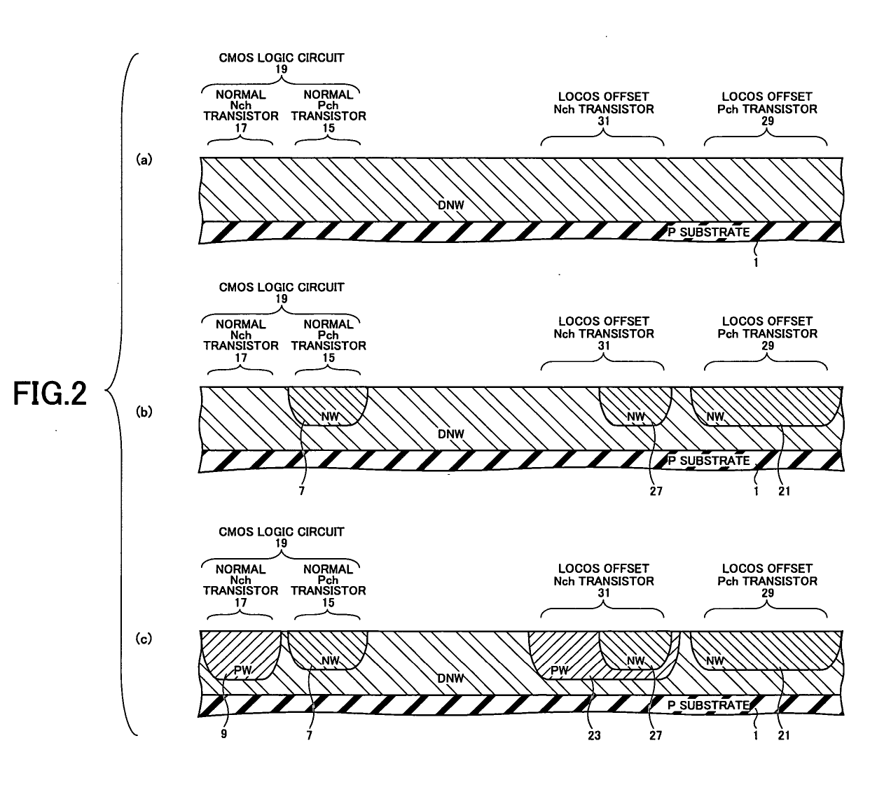

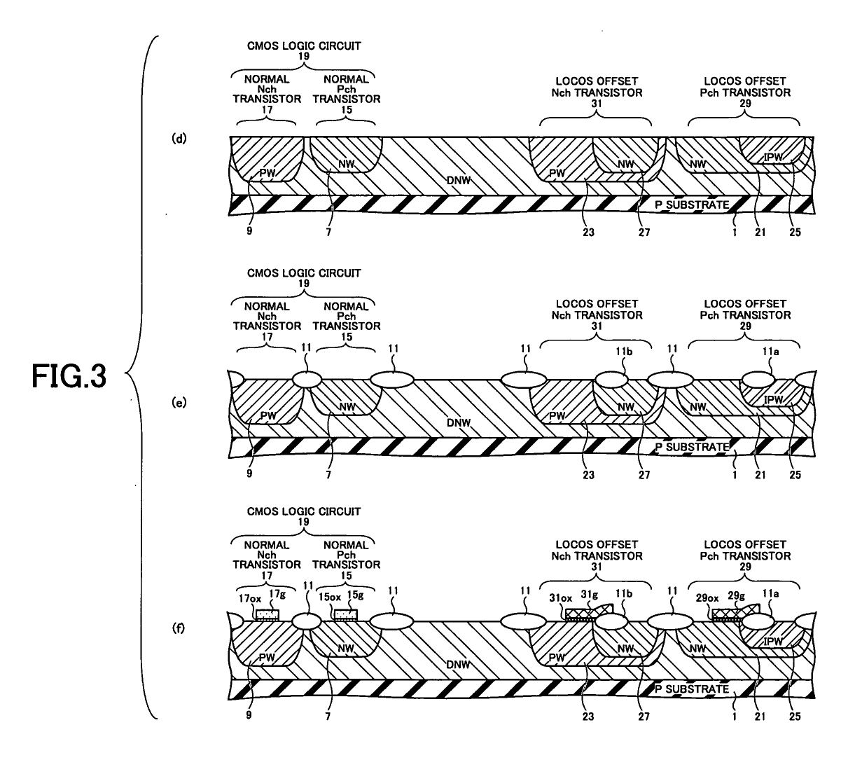

FIGS. 2 and 3 are cross-sectional views showing an example of a method for manufacturing a semiconductor device according to the embodiment shown in FIG. 1.

In a first step, using the photomechanical process, a resist pattern is formed on the P substrate 1 so as to delimit a region of the deep N-well 3. The resist pattern is used as an implantation mask and phosphorus is ion implanted using an ion implantation technique. Ion implantation conditions are as follows: acceleration energy is 160 keV and an amount of implantation is 2×10¹³ cm⁻². By performing heat treatment for 10 hours where temperature is 1150° C. in a nitrogen atmosphere, the implanted phosphorus is driven and diffused. In accordance with this, the deep N-well 3 is formed. Thereafter, the resist pattern is removed (refer to FIG. 2-(a)).

In a second step, using the photomechanical process, a resist pattern is formed on the P substrate 1 so as to delimit a region of the normal N-well 7 including a region of the normal Pch transistor 15, a region of the N-well 21 including a region of the LOCOS offset Pch transistor 29, and a region of the N-type low concentration diffusion layer 27 of the LOCOS offset Nch transistor 31. The resist pattern is used as an implantation mask and phosphorus is ion implanted using the ion implantation technique. Ion implantation conditions are as follows: acceleration energy is 160 keV and an amount of implantation is 1×10¹³ cm⁻². By performing heat treatment for 2 hours where temperature is 1150° C. in a nitrogen atmosphere, the implanted phosphorus is driven and diffused. In accordance with this, the normal N-well 7, the N-well 21, and the N-type low concentration diffusion layer 27 are formed at the same time. Thereafter, the resist pattern is removed (refer to FIG. 2-(b)).

In a third step, using the photomechanical process, a resist pattern is formed on the P substrate 1 so as to delimit a region of the normal P-well 9 including a region of the normal Nch transistor 17 and a region of the P-well 23 including a region of the LOCOS offset Nch transistor 31. The resist pattern is used as an implantation mask and boron is ion implanted using the ion implantation technique. Ion implantation conditions are as follows: acceleration energy is 30 keV and an amount of implantation is 1×10¹³ cm⁻². By performing heat treatment for 1 hour where temperature is 1150° C. in a nitrogen atmosphere, the implanted boron is driven and diffused. In accordance with this, the normal P-well 9 and the P-well 23 are formed at the same time. Thereafter, the resist pattern is removed (refer to FIG. 2-(c)).

In a fourth step, using the photomechanical process, a resist pattern is formed on the P substrate 1 so as to delimit a region of the P-type low concentration diffusion layer 25 of the LOCOS offset Pch transistor 29. The resist pattern is used as an implantation mask and boron is ion implanted using the ion implantation technique. Ion implantation conditions are as follows: acceleration energy is 30 keV and an amount of implantation is 3×10¹³ cm⁻². By performing heat treatment for 1 hour where temperature is 1150° C. in a nitrogen atmosphere, the implanted boron is driven and diffused. In accordance with this, the P-type low concentration diffusion layer 25 is formed. Thereafter, the resist pattern is removed (refer to FIG. 3-(d)).

In a fifth step, using a LOCOS process, the LOCOS oxide film 11, the LOCOS oxide film 11a, and the LOCOS oxide film 11b are formed on the surface of the P substrate 1 at the same time. Conditions of the LOCOS process are as follows: after a photomechanical step of delimiting regions of the LOCOS oxide films including element separating regions is performed, oxidation treatment is performed for 2 hours where temperature is 1000° C. in a wet oxidant atmosphere. The LOCOS oxide film 11 is formed on the element separating region, the LOCOS oxide film 11a is formed on the surface of the P-type low concentration diffusion layer 25, and the LOCOS oxide film 11b is formed on the surface of the N-type low concentration diffusion layer 27 (refer to FIG. 3-(e)).

In a sixth step, the gate oxide films 15ox, 17ox, 29ox, and 31ox are formed at the same time so as to have a thickness of 30 nm on the surface of the P substrate 1. A polysilicon film is deposited on an entire surface of the P substrate 1 so as to have a thickness of 300 nm in a low pressure CVD where deposition temperature is 600° C. After phosphorus is introduced into the polysilicon film so as to have low resistance, a resist pattern for delimiting gate electrodes is formed using the photomechanical process. While the resist pattern is used as an implantation mask, the polysilicon film is patterned through an anisotropic plasma etching using hydrogen bromide. In accordance with this, the gate electrodes 15g, 17g, 29g, and 31g are formed at the same time (refer to FIG. 3-(f)). In FIG. 3-(f), silicon oxide films of other portions formed at the same time with the gate oxide films 15ox, 17ox, 29ox, and 31ox are omitted.

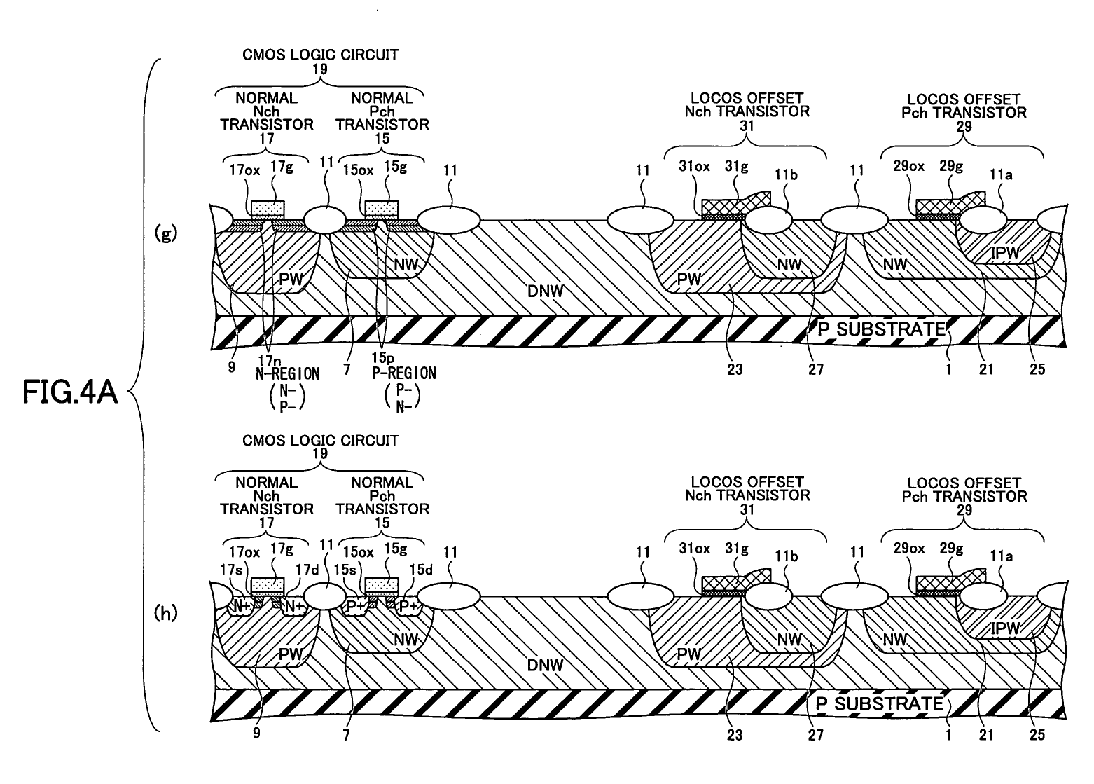

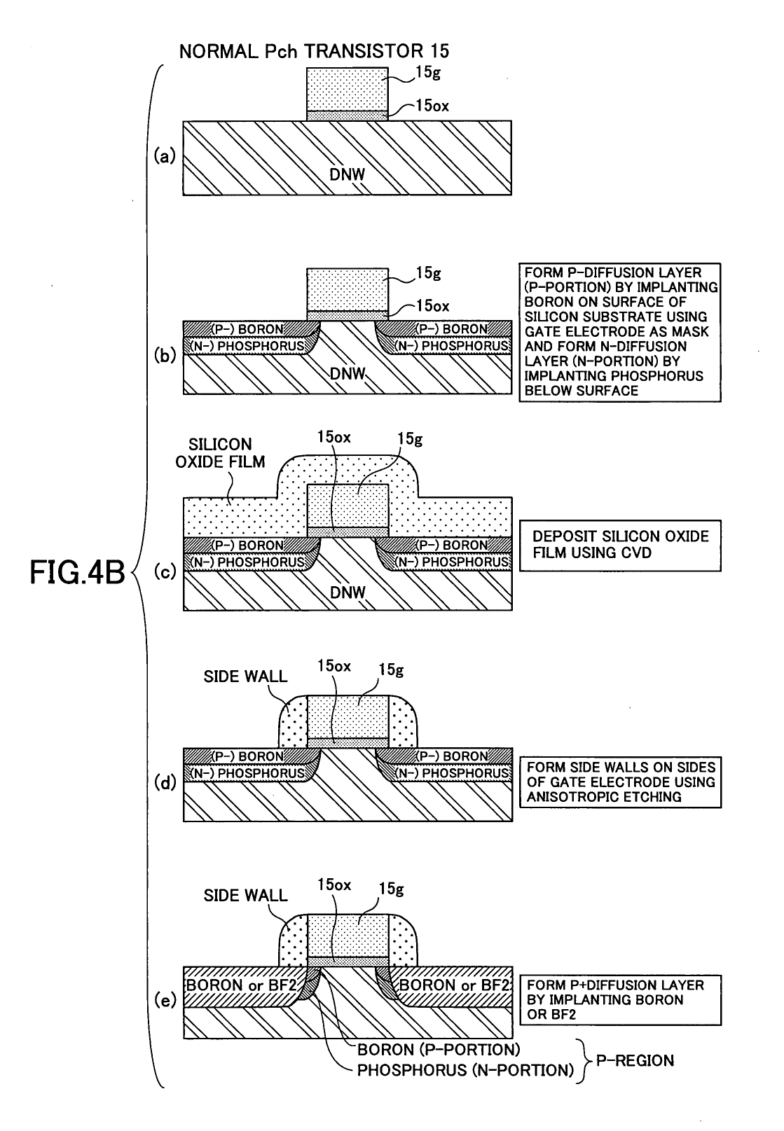

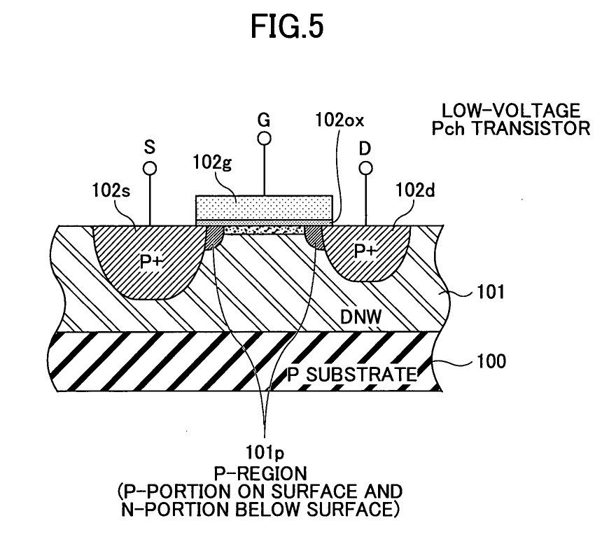

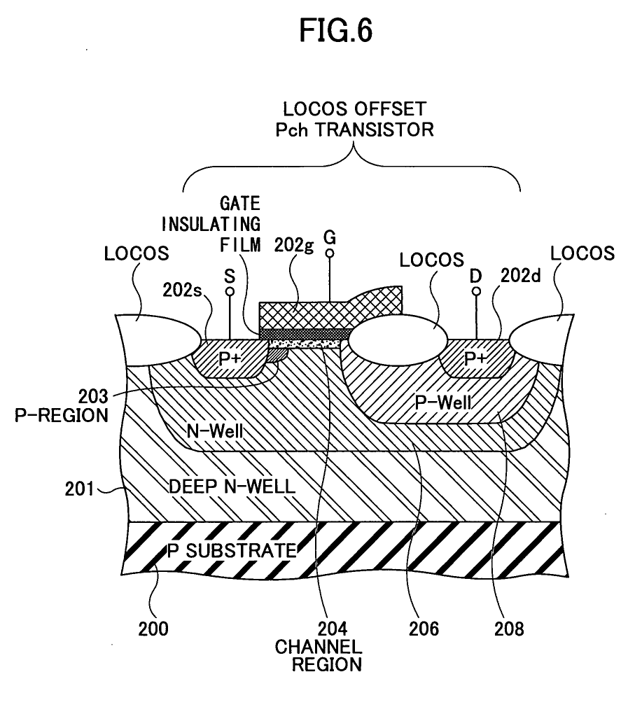

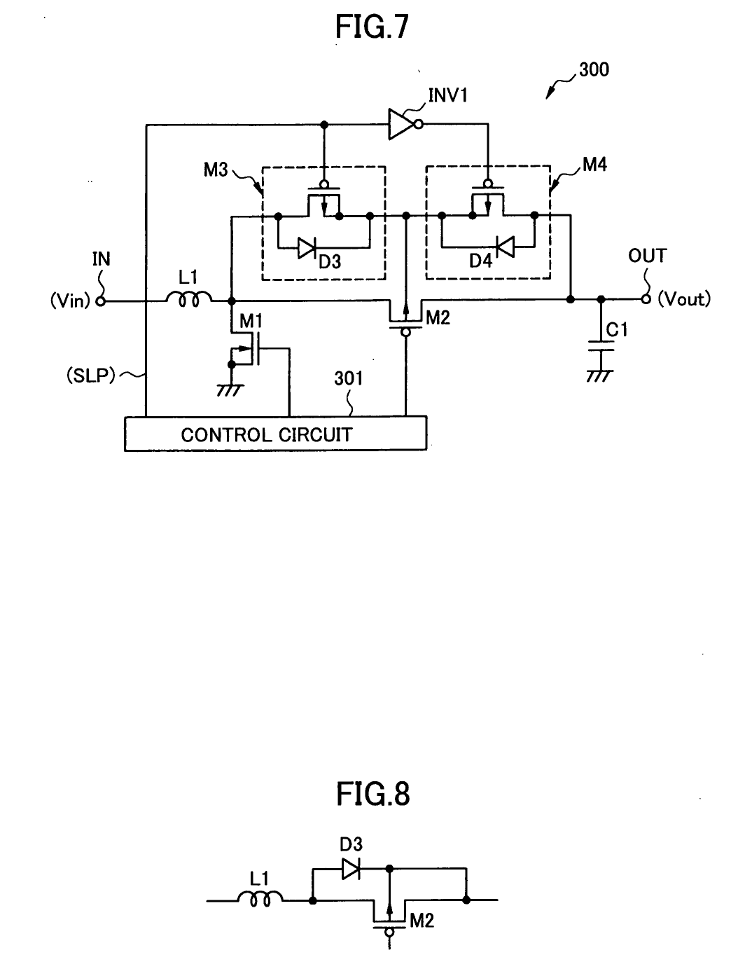

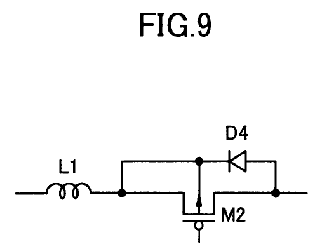

In a seventh step, using the photomechanical process and the ion implantation technique, phosphorus or arsenic is implanted in the surface of the normal P-well 9 and boron is implanted below the surface so as to form an N-type LDD region (N−region). Further, using the photomechanical process and the ion implantation technique, boron or BF₂ is implanted in the surface of the normal N-well 7 and phosphorus is implanted below the surface so as to form a P-type LDD region (P−region) (refer to FIG. 4A-(g)).

Next, using the low pressure CVD method, an anisotropic etching, and the like, LDD side walls are formed on both sides of the gate electrodes 17g and 15g.

Thereafter, using the photomechanical process and the ion implantation technique, phosphorus or arsenic is implanted in the normal P-well 9, the P-well 23, and the N-type low concentration diffusion layer 27. In accordance with this, the source 17s and the drain 17d of the normal Nch transistor 17 and the source 31s and the drain 31d of the LOCOS offset Nch transistor 31 are formed at the same time (refer to FIG. 4A-(h)).

Moreover, boron or BF₂ is implanted in the normal N-well 7, the N-well 21, and the P-type low concentration diffusion layer 25. In accordance with this, the source 15s and the drain 15d of the normal Pch transistor 15 and the source 29s and the drain 29d of the LOCOS offset Pch transistor 29 are formed at the same time.

In the following, a method for forming the P−region in a normal Pch transistor from FIG. 3-(f) is described in detail with reference to FIG. 4B.

From a status of FIG. 4B-(a), namely, a status of FIG. 3-(f), using the gate electrode as a mask, boron is implanted in the surface of the silicon substrate so as to form the P-diffusion layer (P-portion) on the surface and phosphorus is implanted under the surface so as to form the N-diffusion layer (N-portion) (refer to FIG. 4B-(b)).

Next, the silicon oxide film is deposited using the CVD method (refer to FIG. 4B-(c)) and the side walls are formed on sides of the gate electrode using the anisotropic etching (refer to FIG. 4B-(d)).

Thereafter, boron or BF₂ is implanted so as to form the P+diffusion layer (refer to FIG. 4B-(e)). Although this P+diffution layer becomes the source 15s and the drain 15d, because of the side walls are present, the boron (P-portion) is left on the surface extending from the channel and the phosphorus (N-portion) is left below the surface, thereby forming the P−region (LDD region). This P−region reduces an off-leakage current.

As mentioned above, the normal Pch transistor is described in detail with reference to FIG. 4B. However, the same applies in the normal Nch transistor except that opposite materials in terms of P/N conductivity types are used.

As mentioned above, according to the present embodiment, it is possible to form the normal Pch transistor 15 and the normal Nch transistor 17 having the LDD region, and the LOCOS offset Pch transistor 29 and the LOCOS offset Nch transistor 31 without the LDD region on the same P substrate 1 at the same time (refer to FIG. 1).

As mentioned above, according to the present invention, it is possible to form the normal Pch transistor and the normal Nch transistor having the LDD region, and the LOCOS offset Pch transistor and the LOCOS offset Nch transistor without the LDD region on the same P substrate. Thus, it is possible to manufacture semiconductor devices with reduced off-leakage current in the same semiconductor chip in an efficient manner.

The present invention is not limited to the specifically disclosed embodiment, and variations and modifications may be made without departing from the scope of the present invention.

The present application is based on Japanese priority application No. 2006-076028 filed Mar. 20, 2006, the entire contents of which are hereby incorporated herein by reference.

What is claimed is:

1. A semiconductor device comprising:
a semiconductor substrate;
at least one normal transistor disposed on the semiconductor substrate; and
at least one LOCOS offset transistor disposed on the semiconductor substrate, wherein
the normal transistor has an LDD region between a channel and a source and between the channel and a drain, and
the LOCOS offset transistor has no LDD region between a channel and a source and between the channel and a drain.

2. The semiconductor device according to claim 1, wherein
the LDD region includes two low concentration diffusion layer regions of different conductivity types.

3. A method for manufacturing a semiconductor device including a semiconductor substrate, at least one LOCOS offset transistor disposed on the semiconductor substrate, and at least one normal transistor disposed on the semiconductor substrate through a photomechanical process and an ion implantation technique, the method comprising the steps of:
forming a normal N-well including a region of a normal Pch transistor, an N-well including a region of a LOCOS offset Pch transistor, and an N-type low concentration diffusion layer of a LOCOS offset Nch transistor on the semiconductor substrate;
forming a normal P-well including a region of a normal Nch transistor and a P-well including a region of the LOCOS offset Nch transistor;
forming a P-type low concentration diffusion layer of the LOCOS offset Pch transistor;
forming a LOCOS oxide film on a surface of the substrate using a LOCOS process;
forming gate oxide films of the normal Pch transistor, the normal Nch transistor, the LOCOS offset Pch transistor, and the LOCOS offset Nch transistor;
forming an N-type LDD region (N−region) by implanting phosphorus or arsenic in a surface of the normal P-well and implanting boron below the surface;
forming a P-type LDD region (P−region) by implanting boron or BF₂ in a surface of the normal N-well and implanting phosphorus below the surface;
forming LDD side walls on both sides of gate electrodes of the normal Pch transistor and the normal Nch transistor;
forming a source and a drain of the normal Nch transistor and a source and a drain of the LOCOS offset Nch transistor by implanting phosphorus or arsenic in the normal P-well, the P-well including the region of the LOCOS offset Nch transistor, and the N-type low concentration diffusion layer of the LOCOS offset Nch transistor; and
forming a source and a drain of the normal Pch transistor and a source and a drain of the LOCOS offset Pch transistor by implanting boron or BF₂ in the normal N-well, the N-well including the region of the LOCOS offset Pch transistor, and the P-type low concentration diffusion layer of the LOCOS offset Pch transistor.

4. The method for manufacturing a semiconductor device according to claim 3, wherein
one of the normal Pch transistor and the normal Nch transistor is omitted.

5. The method for manufacturing a semiconductor device according to claim 3, wherein
one of the LOCOS offset Pch transistor and the LOCOS offset Nch transistor is omitted.

6. The method for manufacturing a semiconductor device according to claim 4, wherein
one of the LOCOS offset Pch transistor and the LOCOS offset Nch transistor is omitted.
